(19) United States
(12) Patent Application Publication
(10) Pub. No.: US 2026/0231710 A1
(43) Pub. Date: Aug. 6, 2026

(54) BACKSIDE MARKINGS AND MARKING GROOVES FOR WAFER-LEVEL CHIP SCALE PACKAGING DICE

(71) Applicant: Cirrus Logic International Semiconductor Ltd., Edinburgh (GB)

(72) Inventor: Christopher HEALY, Austin, TX (US)

(73) Assignee: Cirrus Logic International Semiconductor Ltd., Edinburgh (GB)

(21) Appl. No.: 19/425,776

(22) Filed: Dec. 18, 2025

Related U.S. Application Data
(60) Provisional application No. 63/752,972, filed on Feb. 3, 2025.

(51) Int. Cl. H10P 58/00; H10P 52/00; H10W 46/00

(52) U.S. Cl. CPC H10P 58/20; H10W 46/503; H10W 46/603; H10P 52/00

(57) ABSTRACT

A wafer may include a plurality of integrated circuit dice each having a frontside with active circuitry and a backside of semiconductor substrate, saw streets defining perimeters of the plurality of integrated circuit dice, and laser-etched marking grooves formed in the backside along the saw streets and configured to inhibit chipping of the semiconductor substrate during singulation of the plurality of integrated circuit dice.

### RELATED APPLICATION

The present disclosure claims priority to United States Provisional Patent Application Ser. No. 63/752,972, filed Feb. 3, 2025, which is incorporated by reference herein in its entirety.

### FIELD OF DISCLOSURE

The present disclosure relates in general to semiconductor fabrication, and more particularly, to the application of certain backside markings and marking grooves for integrated circuit packages, including wafer-level chip-scale packages.

### BACKGROUND

Semiconductor device fabrication is a process used to create integrated circuits that are present in many electrical and electronic devices. Semiconductor device fabrication comprises a multiple-step sequence of photolithographic, mechanical, and chemical processing steps during which electronic circuits are gradually created on a wafer made of semiconducting material, before being singulated into individual integrated circuit dice. For example, during semiconductor device fabrication, numerous discrete circuit components, including transistors, resistors, capacitors, inductors, and diodes, may be formed on a single semiconductor die.

For years, integrated circuits have been fabricated using complementary metal-oxide-semiconductor (CMOS) devices. With the trend towards miniaturization, many CMOS devices are now being assembled in wafer-level chip-scale packages (WLCSP). Generally speaking, fabrication of a WLCSP involves packaging an integrated circuit while the integrated circuit is still part of a semiconductor wafer, in contrast to the more conventional method of slicing the wafer into individual circuits (dice) and then packaging the dice individually. Thus, the resulting package may be practically of the same size as the die. A major application area of WLCSPs is smartphones and similar mobile devices due to size constraints of such devices. For example, functions provided by WLCSPs in smartphones may include sensors, power management, wireless communication, amplifiers, and others.

To slice a wafer into individual circuits (dice), a dicing blade is often used. This singulation process may cause chips to occur in individual dice. To illustrate, FIGS. 1A and 1B illustrate sidewall and backside views, respectively, of an example WLCSP die 1, including a chipping area 10A that may be caused by singulation with a dicing blade. Similarly, FIGS. 1C and 1D illustrate additional sidewall and backside views, respectively, of example WLCSP die 1, including a chipping area 10B that may be caused by singulation with a dicing blade. FIG. 1D also depicts backgrind markings 12 resulting from grinding a backside of a wafer in order to grind such wafer to a desired thickness.

FIG. 1E illustrates a dicing blade 5 cutting a die 20 from a wafer 25. Arrows 50 of FIG. 1E show directions of rotation and feed of blade 5 as blade 5 singulates die 20 from the wafer 25. In FIG. 1E, as blade 5 singulates die 20 from wafer 25, blade 5 may cause an area (such as an area of substrate material of die 20 and wafer 25) to be removed or chipped off from die 20, creating a chipping area 10B that starts from where blade 5 is moved from the initiation position 30 through a chip propagation area 40.

Chipping areas in dice may undesirable, and the existence of such chipping areas in a die may be representative of damage, functional impact, or imperfections of the die that purchasers of the dice may raise as issues. Thus, systems and methods for minimizing or eliminating such chipping when dice are cut from wafers may be desired.

### SUMMARY

In accordance with the teachings of the present disclosure, certain disadvantages and problems associated with singulating a wafer into integrated circuit packages may be reduced or eliminated.

In accordance with embodiments of the present disclosure, a wafer may include a plurality of integrated circuit dice each having a frontside with active circuitry and a backside of semiconductor substrate, saw streets defining perimeters of the plurality of integrated circuit dice, and laser-etched marking grooves formed in the backside along the saw streets and configured to inhibit chipping of the semiconductor substrate during singulation of the plurality of integrated circuit dice.

In accordance with these and other embodiments of the present disclosure, a method of fabricating integrated circuit package dice may include laser etching a backside of a semiconductor wafer along markings to form marking grooves that define saw streets corresponding to perimeters of dice on the wafer and singulating the semiconductor wafer into individual dice by cutting along the marking grooves with a dicing blade, wherein the marking grooves inhibit chipping of the semiconductor wafer substrate during singulation.

In accordance with these and other embodiments of the present disclosure, a singulated die may include the frontside including active circuitry, a backside comprising a semiconductor substrate, a perimeter defining edges of the die, sidewalls substantially perpendicular to the backside at the perimeter, and remnants of laser-etched marking grooves formed on the backside prior to singulation of the singulated die, the remnants extending from the sidewalls.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1A illustrates a sidewall view of an example WLCSP die with a chipping area caused by singulation with a dicing blade, as is known in the art;

FIG. 1B illustrates a backside view of an example WLCSP die with a chipping area caused by singulation with a dicing blade, as is known in the art;

FIG. 1C illustrates another sidewall view of an example WLCSP die with a chipping area caused by singulation with a dicing blade, as is known in the art;

FIG. 1D illustrates another backside view of an example WLCSP die with a chipping area caused by singulation with a dicing blade, as is known in the art;

FIG. 1E illustrates a dicing blade cutting a die from a wafer, as is known in the art;

FIG. 2 illustrates grinding of a backside of a wafer by a grinder, in accordance with embodiments of the present disclosure;

FIG. 3 illustrates laser etching of a backside of a wafer by a laser, in accordance with embodiments of the present disclosure;

FIG. 4A illustrates a plan view of a portion of a backside of a wafer etched by a laser along markings to form marking grooves, in accordance with embodiments of the present disclosure;

FIG. 4B illustrates a side cross-sectional elevation view of a portion of a wafer etched by a laser along markings to form marking grooves, in accordance with embodiments of the present disclosure;

FIG. 4C illustrates a plan view of a wafer etched by a laser along markings to form marking grooves, in accordance with embodiments of the present disclosure;

FIG. 5 illustrates singulation of dice from a wafer, in accordance with embodiments of the present disclosure;

FIG. 6 illustrates a plan view of a backside of a die with typical markings without marking grooves, as is known in the art;

FIG. 7 illustrates a plan view of a backside of a portion of a wafer with typical markings without marking grooves after singulation of dice, as is known in the art; and

FIG. 8 illustrates a plan view of a backside of a portion of a wafer with marking grooves after singulation of dice, in accordance with embodiments of the present disclosure.

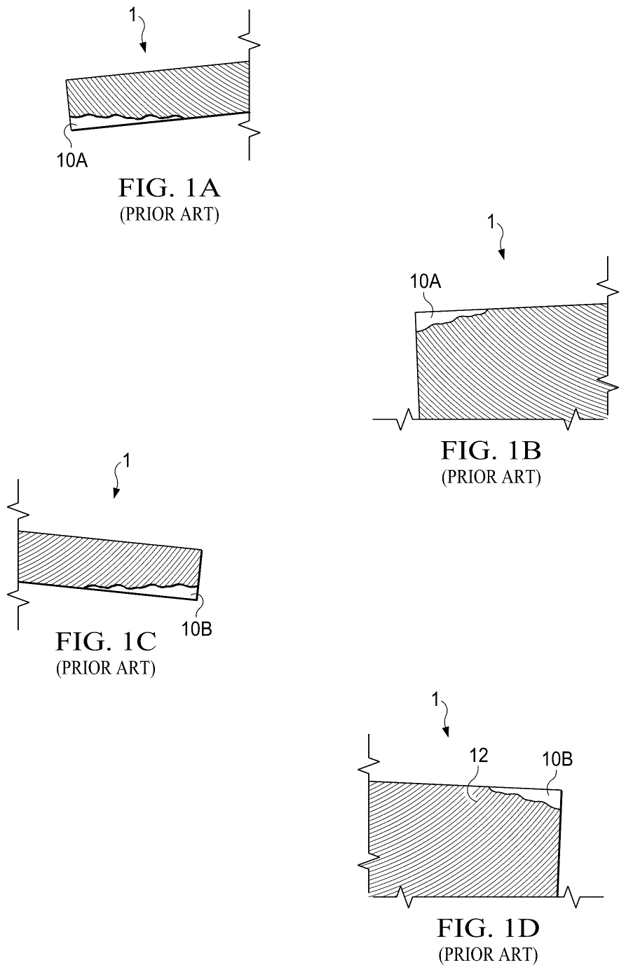

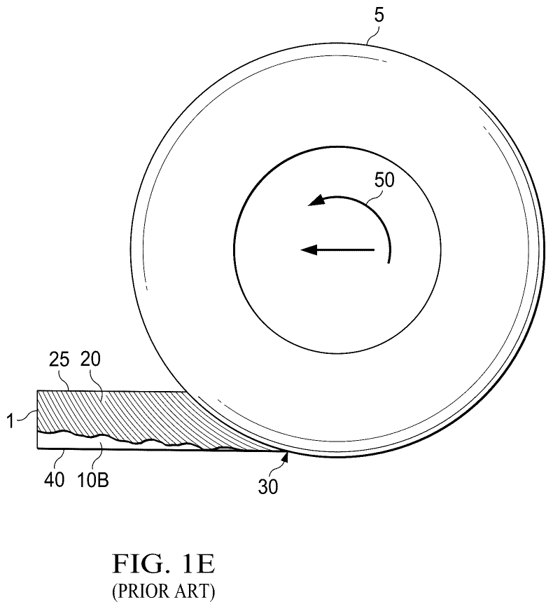

### DETAILED DESCRIPTION

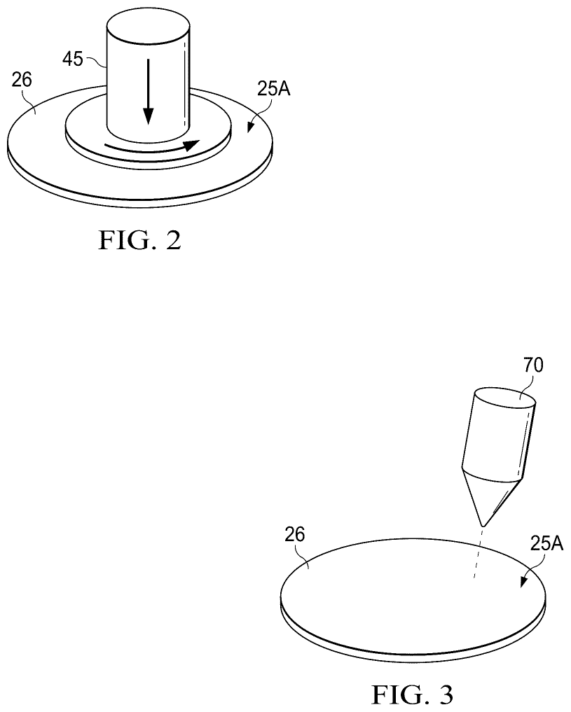

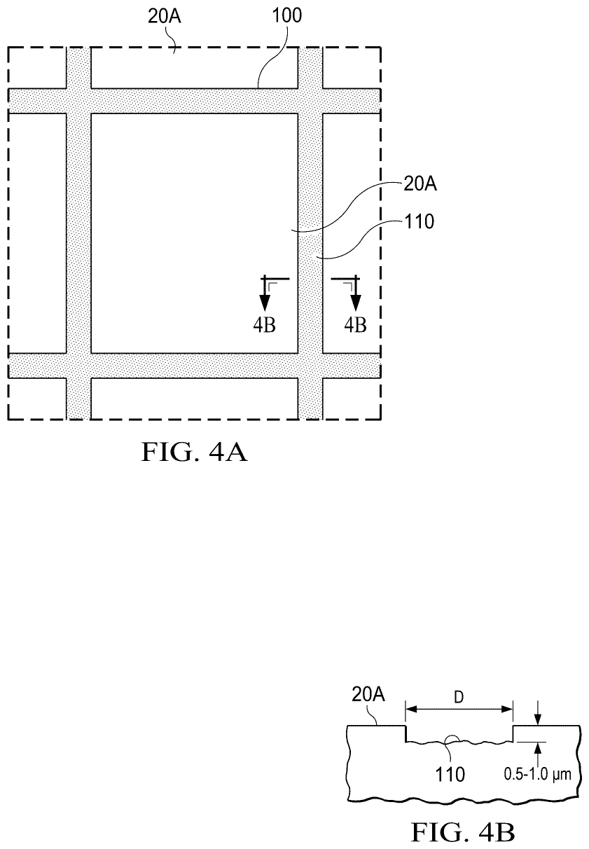

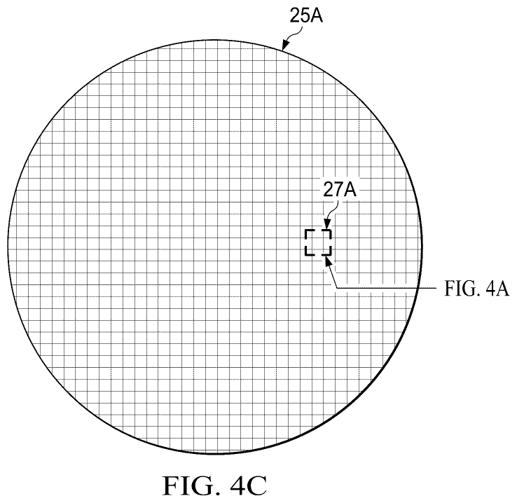

FIG. 2 illustrates grinding of a backside 26 of a wafer 25A by a grinder 45, in accordance with embodiments of the present disclosure. FIG. 3 illustrates laser etching of backside 26 of wafer 25A by a laser 70, in accordance with embodiments of the present disclosure. FIG. 4A illustrates a plan view of a portion of backside 26 of wafer 25A etched by laser 70 along markings 100 to form marking grooves 110 into the surface of backside 26, in accordance with embodiments of the present disclosure. FIG. 4B illustrates a side cross-sectional elevation view of a portion of wafer 25A etched by laser 70 along markings 100 to form marking grooves 110, in accordance with embodiments of the present disclosure. FIG. 4C illustrates a plan view of wafer 25A etched by laser 70 along markings 100 to form marking grooves 110, in accordance with embodiments of the present disclosure.

After grinding of backside 26 as shown in FIG. 2, resulting in backgrind marks on the surface of backside 26, laser 70 may laser etch backside 26 of wafer 25A as shown in FIG. 3. As shown in FIG. 4A, laser 70 may laser etch backside 26 along markings 100 to form marking grooves 110 that define saw streets. As shown in FIG. 4B, laser 70 may etch marking grooves 110 to a depth of approximately 0.5 μm to approximately 1.0 μm and a width of d, wherein width d may be dependent on a thickness of blade 5 used to singulate wafer 25A. Marking grooves 110 may be located along perimeters 27A of various dice 20A singulated from wafer 25A. Thus, marking grooves 110 may define saw streets used to cut along perimeters 27A of each die 20A.

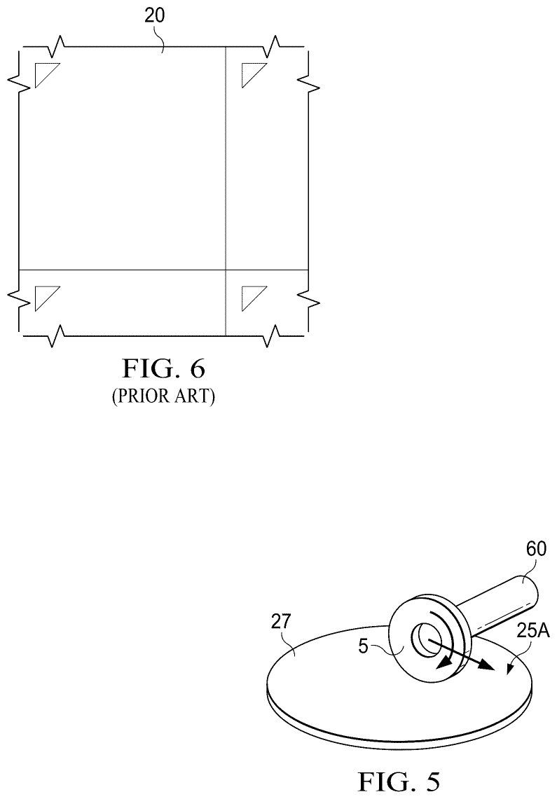

FIG. 5 illustrates singulation of dice 20A from wafer 25A, in accordance with embodiments of the present disclosure. As shown in FIG. 5, after etching of marking grooves 110 as shown in FIGS. 4A-4C, die saw 60 having a rotating dicing blade 5 may cut wafer 25A along the various marking grooves 110 to singulate dice 20A from wafer 25A. As described in greater detail below, the process of forming marking grooves 110 prior to cutting may minimize or eliminate chipping (e.g., chipping of substrate material) of various dice 20A. In other words, the backside and sidewall chipping of die 20A is minimized or avoided by using laser marks 100 for marking grooves 110. Such introduction of micro damage to define saw streets of marking grooves 110 may eliminate fracture propagation as a result of one or more of unifying grinding performance observed by dicing blade 5, providing a stop for lateral crack propagation, facilitating breakthrough of blade 5 that prevents and/or minimizes tear out leading to chipping of backside 26, and other factors.

For comparison, FIG. 6 illustrates a plan view of a backside of a die 20 with typical markings without marking grooves, as is known in the art.

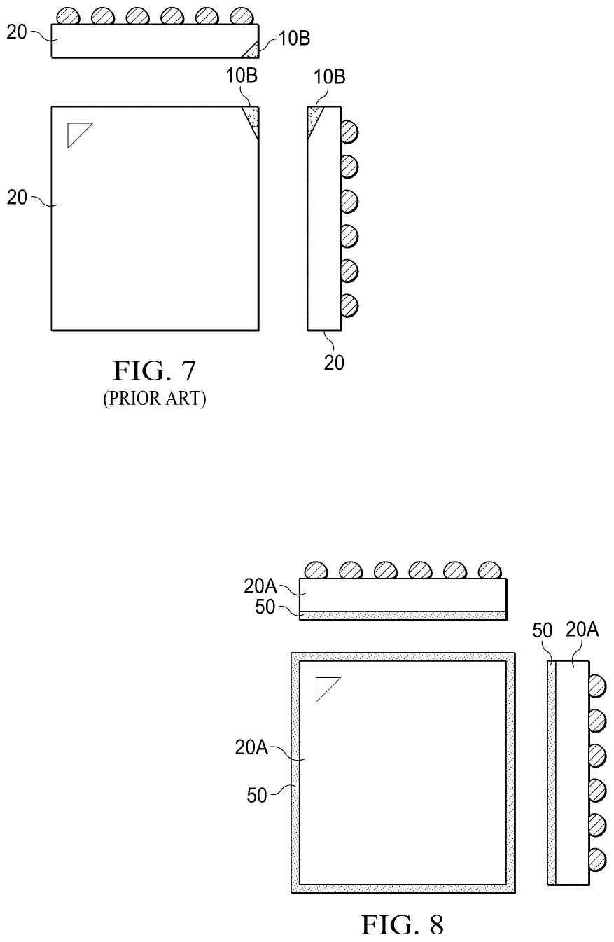

FIG. 7 illustrates a plan view of a backside of a portion of a wafer with typical markings without marking grooves, shown after singulation of dice 20, as is known in the art. As shown in FIG. 7, die 20 may include chipping or a chip out area 10B.

By contrast, FIG. 8 illustrates plan view of a portion of a backside 26 of wafer 25A with marking grooves, shown after singulation of dice 20A, in accordance with embodiments of the present disclosure. In using markings 100 and marking grooves 110, chipping and/or chip out areas of dice 20A may be minimized or avoided. FIG. 8 further shows that a singulated die 20A may have remnants 50 of the markings 100 and/or marking grooves 110 after the edges of die 20A are cut along die perimeter 27A during the die singulation process.

As a result of the systems and methods described above, a die 20A may result having a frontside and a backside (e.g., backside 26), with sharp sidewalls adjacent to and substantially perpendicular to the backside, with a rough step on the sides of die 20A corresponding to remnants 50 extending from the sidewalls.

In summary, a die 20A may comprise a perimeter 27A, a backside 26 having substrate material, and a frontside opposite the backside having circuitry, package redistribution layers, and/or solder balls. Marking grooves 110 may be etched along the perimeter 27A of backside 26 of die 20A. Marking grooves 110 may prevent chipping of the substrate material of die 20A when die 20A is being cut from wafer 25A, such as by using a die saw 60 with a dicing blade 5. Marking grooves 110 may result in remnants 50 on the cut die 20A as a result of the backside marking, etching, and cutting processes. Die edges may be cut during the die singulation process along die perimeter 27A.

A method of marking a wafer and singulating a wafer into dice is provided. The method may include etching marking grooves 110 along perimeters 27A of backsides of dice 20A wherein marking grooves 110 prevent chipping of the substrate materials of the dice, and the method may further include cutting marking grooves 110 along perimeters 27A of dice 20A to prevent chipping of the substrate materials.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

Further, reciting in the appended claims that a structure is “configured to” or “operable to” perform one or more tasks is expressly intended not to invoke 35 U.S.C. §112(f) for that claim element. Accordingly, none of the claims in this application as filed are intended to be interpreted as having means-plus-function elements. Should Applicant wish to invoke § 112(f) during prosecution, Applicant will recite claim elements using the “means for [performing a function]” construct.

What is claimed is:

1. A wafer comprising:
a plurality of integrated circuit dice each having a frontside with active circuitry and a backside of semiconductor substrate;
saw streets defining perimeters of the plurality of integrated circuit dice; and
laser-etched marking grooves formed in the backside along the saw streets and configured to inhibit chipping of the semiconductor substrate during singulation of the plurality of integrated circuit dice.

2. The wafer of claim 1, wherein the laser-etched marking grooves have a depth between approximately 0.5 μm and approximately 1.0 μm.

3. The wafer of claim 1, wherein a width of each laser-etched marking groove is selected as a function of a thickness of a dicing blade to be used for singulation.

4. The wafer of claim 1, wherein the laser-etched marking grooves define a grid corresponding to orthogonal dicing lanes for singulation.

5. The wafer of claim 1, wherein the laser-etched marking grooves are configured to provide a stop for lateral crack propagation during blade entry and exit.

6. The wafer of claim 1, wherein the laser-etched marking grooves are formed by scanning a laser beam along markings corresponding to the saw streets.

7. The wafer of claim 1, wherein the laser-etched marking grooves are formed to a depth and morphology sufficient to facilitate breakthrough of a rotating dicing blade and minimize tear-out at the backside.

8. A method of fabricating integrated circuit package dice, the method comprising:
laser etching a backside of a semiconductor wafer along markings to form marking grooves that define saw streets corresponding to perimeters of dice on the wafer; and
singulating the semiconductor wafer into individual dice by cutting along the marking grooves with a dicing blade, wherein the marking grooves inhibit chipping of the semiconductor wafer substrate during singulation.

9. The method of claim 8, further comprising grinding a backside of the semiconductor wafer to a target thickness prior to laser etching.

10. The method of claim 8, wherein laser etching comprises forming the marking grooves to a depth between approximately 0.5 μm and approximately 1.0 μm.

11. The method of claim 8, wherein laser etching comprises forming the marking grooves to a width correlated to a thickness of the dicing blade.

12. The method of claim 8, wherein laser etching comprises scanning a laser beam along orthogonal markings to form a grid of marking grooves corresponding to orthogonal saw streets.

13. The method of claim 8, wherein the cutting along the marking grooves produces die edges substantially perpendicular to the backside and leaves remnants of the marking grooves on sidewalls of the singulated dice.

14. A singulated die comprising:
the frontside including active circuitry;
a backside comprising a semiconductor substrate;
a perimeter defining edges of the die;
sidewalls substantially perpendicular to the backside at the perimeter; and
remnants of laser-etched marking grooves formed on the backside prior to singulation of the singulated die, the remnants extending from the sidewalls.

15. The singulated die of claim 14, wherein the remnants form a step-like discontinuity extending laterally from the sidewalls and having a depth corresponding to a laser-etched groove intersected by a mechanical dicing blade.
